(19) United States
(12) Patent Application Publication
(10) Pub. No.: US 2026/0040864 A1
(43) Pub. Date: Feb. 5, 2026

(54) ETCHING DEVICE, WINDOW MANUFACTURING METHOD, AND ELECTRONIC DEVICE INCLUDING THE WINDOW

(71) Applicant: Samsung Display Co., Ltd., Yongin-si (KR)

(72) Inventors: Myungsun JI, Yongin-si (KR); KIHYUN KIM, Yongin-si (KR); BEOMGYU CHOI, Yongin-si (KR)

(21) Appl. No.: 19/211,907

(22) Filed: May 19, 2025

(30) Foreign Application Priority Data
Jul. 30, 2024 (KR) 10-2024-0101219

(51) Int. Cl. H01L 21/67; H10H 29/01; H10H 29/85; H10K 59/80; H10K 71/00; H10K 102/00

(52) U.S. Cl. CPC H01L 21/6708; H10H 29/036; H10K 71/00; H10H 29/8506; H10K 59/87; H10K 2102/311

(57) ABSTRACT

An etching device includes a stage on a target substrate, and a nozzle part opposing the stage with the target substrate therebetween. The stage includes a first surface parallel to a plane defined by a first direction and a second direction crossing the first direction, and a second surface parallel to a third direction which forms a first angle with the second direction, and the second surface includes a first side parallel to the first direction, and a second side opposing the first side in the third direction and adjacent to the first surface. The nozzle part includes a (1-1)-th nozzle, a (1-2)-th nozzle spaced apart from the (1-1)-th nozzle in the first direction, and a (2-1)-th nozzle disposed between the (1-1)-th nozzle and the (1-2)-th nozzle.

This application claims priority to Korean Patent Application No. 10-2024-0101219, filed on Jul. 30, 2024, and all the benefits accruing therefrom under 35U.S.C. § 119, the content of which in its entirety is herein incorporated by reference.

### BACKGROUND

### 1. Field

The invention herein relates to an etching device and a method for manufacturing a window, and more particularly, to an etching device capable of manufacturing a foldable window, and a method for manufacturing the foldable window.

### 2. Description of Related Art

A display device includes a display area activated in response to an electrical signal. The display device may detect an input applied from the outside through the display area and also display various images to provide information for a user.

### SUMMARY

The invention provides an etching device capable of manufacturing a window with a foldable characteristic and with improved reliability.

The invention also provides a window manufacturing method capable of manufacturing a window with a foldable characteristic and with improved reliability through a simple process.

An embodiment provides an etching device including a stage on which a target substrate is disposed, and a nozzle part opposing the stage with the target substrate disposed therebetween. The stage includes a first surface directed parallel to a plane defined by a first direction and a second direction crossing the first direction, and a second surface directed parallel to a third direction which forms a first angle with the second direction, and the second surface includes a first side directed parallel to the first direction, and a second side opposing the first side in the third direction and disposed adjacent to the first surface. The nozzle part includes a (1-1)-th nozzle, a (1-2)-th nozzle spaced apart from the (1-1)-th nozzle in the first direction, and a (2-1)-th nozzle disposed between the (1-1)-th nozzle and the (1-2)-th nozzle. Each of the (1-1)-th nozzle and the (1-2)-th nozzle provides deionized water toward the first side, and the (2-1)-th nozzle provides a first etchant toward the first side.

In an embodiment, the first angle may be about 1° to about 10°.

In an embodiment, the first etchant may include a fluorine-containing compound.

In an embodiment, a distance by which the (1-1)-th nozzle and the (1-2)-th nozzle are spaced from each other in the first direction may be about 1 mm to about 30 mm.

In an embodiment, a distance by which the (1-1)-th nozzle and the (2-1)-th nozzle are spaced from each other in the first direction, and a distance by which the (2-1)-th nozzle and the (1-2)-th nozzle are spaced from each other in the first direction, may be each independently about 0.5 mm to about 15 mm.

In an embodiment, a distance by which the (1-1)-th nozzle and the (2-1)-th nozzle are spaced from each other in the first direction, and a distance by which the (2-1)-th nozzle and the (1-2)-th nozzle are spaced from each other in the first direction, may be substantially the same.

In an embodiment, the nozzle part may include a (1-3)-th nozzle spaced apart from the (1-2)-th nozzle in the first direction, a (1-4)-th nozzle spaced apart from the (1-3)-th nozzle in the first direction, and a (2-2)-th nozzle disposed between the (1-3)-th nozzle and the (1-4)-th nozzle. Each of the (1-3)-th nozzle and the (1-4)-th nozzle may provide deionized water toward the first side, and the (2-2)-th nozzle may provide a second etchant directed toward the first side.

In an embodiment, the nozzle part may further include a (1-5)-th nozzle, a (1-6)-th nozzle spaced apart from the (1-5)-th nozzle in the first direction, and a (2-3)-th nozzle disposed between the (1-5)-th nozzle and the (1-6)-th nozzle. Each of the (1-5)-th nozzle and the (1-6)-th nozzle may provide deionized water toward the first side, and the (2-3)-th nozzle may provide a third etchant toward the first side. The (1-5)-th nozzle may be spaced apart from the (1-1)-th nozzle in the third direction, the (1-6)-th nozzle may be spaced apart from the (1-2)-th nozzle in the third direction, and the (2-3)-th nozzle may be spaced apart from the (2-1)-th nozzle in the third direction.

In an embodiment, a method for manufacturing a window includes providing a stage including a first surface directed parallel to a plane defined by a first direction and a second direction crossing the first direction, and a second surface directed parallel to a third direction which forms a first angle with the second direction, disposing, on the second surface, a target substrate including a third surface directed parallel to the third direction, disposing a nozzle part so as to oppose the stage with the target substrate therebetween, the nozzle part including a (1-1)-th nozzle, a (1-2)-th nozzle spaced apart from the (1-1)-th nozzle in the first direction, and a (2-1)-th nozzle disposed between the (1-1)-th nozzle and the (1-2)-th nozzle, and forming a preliminary window mother substrate, the forming of the preliminary window mother substrate including providing deionized water on the third surface by each of the (1-1)-th nozzle and the (1-2)-th nozzle and providing a first etchant on the third surface by the (2-1)-th nozzle. The third surface includes a third side directed parallel to the first direction, and a fourth side opposing the third side in the third direction and disposed adjacent to the first surface, and each of the (1-1)-th nozzle, the (1-2)-th nozzle, and the (2-1)-th nozzle is disposed adjacent to the third side.

In an embodiment, the first etchant may include a fluorine-containing compound.

In an embodiment, the target substrate may include a preliminary first non-folding portion, a preliminary second non-folding portion spaced apart from the preliminary first non-folding portion in the first direction, and a preliminary first folding portion disposed between the preliminary first non-folding portion and the preliminary second non-folding portion. In the forming of the preliminary window mother substrate, the deionized water may be provided on each of the preliminary first non-folding portion and the preliminary second non-folding portion, and the first etchant may be provided on the preliminary first folding portion.

In an embodiment, in the forming of the preliminary window mother substrate, the deionized water provided on the preliminary first non-folding portion through the (1-1)-th nozzle may form a first deionized fluid flowing in the third direction, the deionized water provided on the preliminary second non-folding portion through the (1-2)-th nozzle may form a second deionized fluid flowing in the third direction, and the first etchant provided on the preliminary first folding portion through the (2-1)-th nozzle may form a first etching fluid flowing in the third direction. A part of the first deionized fluid and a part of the first etching fluid may be mixed to form a first mixed fluid flowing in the third direction, and a part of the second deionized fluid and a part of the first etching fluid may be mixed to form a second mixed fluid flowing in the third direction. A concentration of the fluorine-containing compound in the first etching fluid may be higher than each of a concentration of the fluorine-containing compound in the first mixed fluid and a concentration of the fluorine-containing compound in the second mixed fluid.

In an embodiment, in the forming of the preliminary window mother substrate, each of the deionized water and the first etchant may flow in the third direction.

In an embodiment, the method for manufacturing the window may further include, after the forming of the preliminary window mother substrate, forming a plurality of windows from the preliminary window mother substrate. Each of the plurality of windows may include a first non-folding portion, a second non-folding portion spaced apart from the first non-folding portion on a plane, and a folding portion disposed between the first non-folding portion and the second non-folding portion on a plane. A thickness of the folding portion may be less than each of a thickness of the first non-folding portion and a thickness of the second non-folding portion.

In an embodiment, each of a portion disposed adjacent to a boundary between the first non-folding portion and the folding portion and a portion disposed adjacent to a boundary between the second non-folding portion and the folding portion may be formed to be curved.

In an embodiment, a width of the folding portion in the first direction may be about 1 mm to about 25 mm.

In an embodiment, the nozzle part may include a (1-3)-th nozzle spaced apart from the (1-2)-th nozzle in the first direction, a (1-4)-th nozzle spaced apart from the (1-3)-th nozzle in the first direction, and a (2-2)-th nozzle disposed between the (1-3)-th nozzle and the (1-4)-th nozzle, and the forming of the preliminary window mother substrate may further include providing deionized water toward the third surface by each of the (1-3)-th nozzle and the (1-4)-th nozzle, and providing a second etchant toward the third surface by the (2-2)-th nozzle. Each of the (1-3)-th nozzle, the (1-4)-th nozzle, and the (2-2)-th nozzle may be disposed adjacent to the third side.

In an embodiment, the nozzle part may further include a (1-5)-th nozzle, a (1-6)-th nozzle spaced apart from the (1-5)-th nozzle in the first direction, and a (2-3)-th nozzle disposed between the (1-5)-th nozzle and the (1-6)-th nozzle, and the forming of the preliminary window mother substrate may further include providing deionized water toward the third surface by each of the (1-5)-th nozzle and the (1-6)-th nozzle, and providing a third etchant toward the third surface by the (2-3)-th nozzle. The (1-5)-th nozzle may be spaced apart from the (1-1)-th nozzle in the third direction, the (1-6)-th nozzle may be spaced apart from the (1-2)-th nozzle in the third direction, and the (2-3)-th nozzle may be spaced apart from the (2-1)-th nozzle in the third direction.

In an embodiment, the target substrate may include a preliminary first non-folding portion, a preliminary second non-folding portion spaced apart from the preliminary first non-folding portion in the first direction, and a preliminary first folding portion disposed between the preliminary first non-folding portion and the preliminary second non-folding portion. In the forming of the preliminary window mother substrate, the deionized water may be provided on each of the preliminary first non-folding portion and the preliminary second non-folding portion, and the first etchant may be provided on the preliminary first folding portion.

In an embodiment, an electronic device includes a display module, an upper module comprising a window disposed above the display module and, a lower module disposed below the display module. The window includes a first non-folding portion, a second non-folding portion spaced apart from the first non-folding portion on a plane, and a folding portion disposed between the first non-folding portion and the second non-folding portion on the plane. Each of a portion disposed adjacent to a boundary between the first non-folding portion and the folding portion and a portion disposed adjacent a boundary between the second non-folding portion and the folding portion is curved.

### BRIEF DESCRIPTION OF THE FIGURES

The accompanying drawings are included to provide a further understanding of the invention and are incorporated in and constitute a part of this specification. The drawings illustrate embodiments of the invention and, together with the description, serve to explain principles of the invention. In the drawings:

FIG. 1A is a perspective view of an electronic device, according to an embodiment;

FIG. 1B is a perspective view of an electronic device, according to an embodiment;

FIG. 1C is a perspective view of an electronic device, according to an embodiment;

FIG. 2 is an exploded perspective view of an electronic device, according to an embodiment;

FIG. 3A is a cross-sectional view of the electronic device taken along line I-I′ in FIG. 2, according to an embodiment;

FIG. 3B is a cross-sectional view of the electronic device taken along line I-I′ in FIG. 2, according to an embodiment;

FIG. 4 is a perspective view of an etching device, according to an embodiment;

FIG. 5 is an exploded perspective view of an etching device, according to an embodiment;

FIG. 6 is a cross-sectional view of the etching device taken along line II-II′ in FIG. 4, according to an embodiment;

FIG. 7 is a perspective view of an etching device, according to an embodiment;

FIG. 8 is a flowchart of a method for manufacturing a window, according to an embodiment;

FIG. 9 is a view illustrating some of a method for manufacturing a window, according to an embodiment;

FIG. 10 is a view illustrating some of a method for manufacturing a window, according to an embodiment;

FIG. 11 is a view illustrating some of a method for manufacturing a window, according to an embodiment;

FIG. 12 is a view illustrating some of a method for manufacturing a window, according to an embodiment;

FIG. 13 is a view illustrating some of a method for manufacturing a window, according to an embodiment;

FIG. 14 is a view illustrating some of a method for manufacturing a window, according to an embodiment;

FIG. 15 is a perspective view of a window, according to an embodiment; and

FIG. 16 is a cross-sectional view of the window taken along line III-III′ in FIG. 15, according to an embodiment.

### DETAILED DESCRIPTION

In the present disclosure, it will be understood that when an element (or region, layer, section, etc.) is referred to as being “on”, “connected to” or “coupled to” another element, it can be disposed directly on, connected or coupled to the other element or a third intervening elements may be disposed between the elements.

Like reference numbers or symbols refer to like elements throughout. In addition, in the drawings, the thickness, the ratio, and the dimension of elements are exaggerated for effective description of the technical contents. The term “and/or” includes one or more combinations which may be defined by relevant elements.

It will be understood that, although the terms first, second, etc. may be used herein to describe various elements, these elements should not be limited by these terms. These terms are only used to distinguish one element from another element. For example, a first element could be termed a second element without departing from the teachings of the present invention, and similarly, a second element could be termed a first element. As used herein, the singular forms are intended to include the plural forms as well, unless the context clearly indicates otherwise.

In addition, the terms, such as “below”, “beneath”, “on” and “above”, are used for explaining the relation of elements shown in the drawings. The terms are relative concept and are explained based on the direction shown in the drawing.

It will be further understood that the terms such as “includes” or “has”, when used herein, specify the presence of stated features, numerals, steps, operations, elements, parts, or the combination thereof, but do not preclude the presence or addition of one or more other features, numerals, steps, operations, elements, parts, or the combination thereof.

As used herein, “being directly disposed” may mean that there is no additional layer, film, region, plate or the like between a part such as a layer, film, region, plate or the like and another part. For example, “being directly disposed” may mean that two layers or two members are disposed with no additional member such as an adhesive member.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the invention will be described with reference to the accompanying drawings.

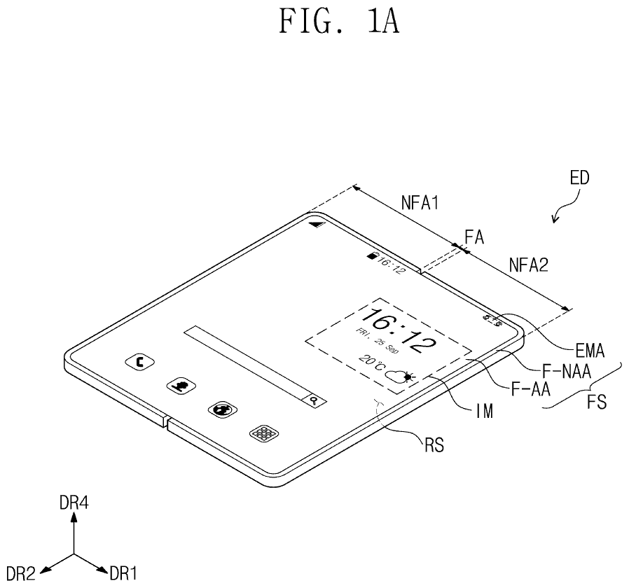

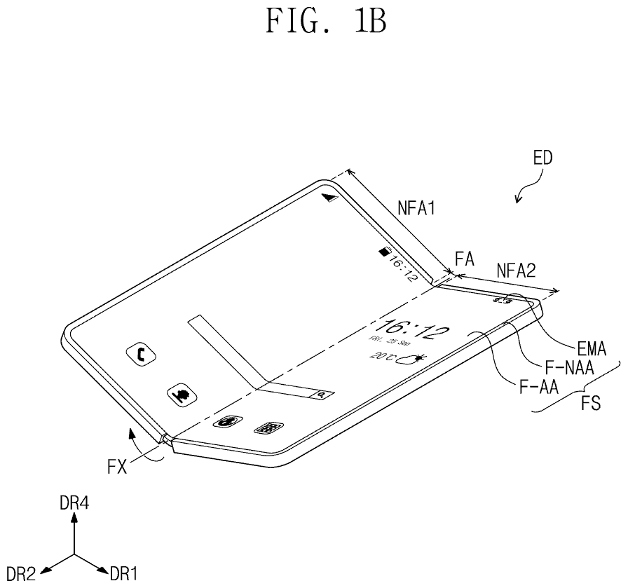

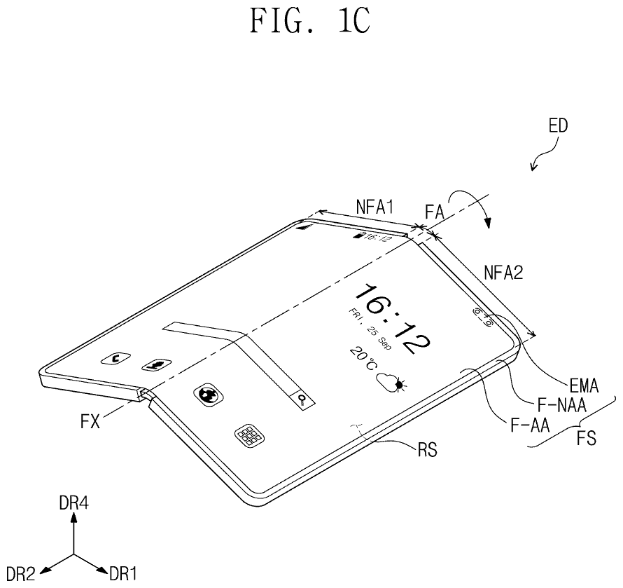

FIGS. 1A to 1C are perspective views of an electronic device, according to an embodiment. FIG. 1A illustrates a spread state, and FIGS. 1B and 1C illustrate folded states, according to an embodiment.

In an embodiment, in FIGS. 1A to 1C, a display device ED is illustrated as a foldable display device changed in shape to a folded shape. However, the invention is not limited thereto, and the display device ED according to another embodiment may be a flexible display device having a shape which may be changed by bending or rolling.

In an embodiment, the display device ED may include a display surface FS defined by a first direction DR1 and a second direction DR2 crossing the first direction DR1. The display device ED may provide an image IM for a user through the display surface FS. The display device ED, according to an embodiment, may display the image IM in a third direction DR3 on the display surface FS which is directed parallel to each of the first direction DR1 and the second direction DR2.

In an embodiment, the display surface FS of the display device ED may include an active area F-AA and a peripheral area F-NAA. The active area F-AA may be an area that is activated in response to an electrical signal. The display device ED, according to an embodiment, may display the image IM through the active area F-AA. The active area F-AA may detect various types of external inputs. The peripheral area F-NAA is disposed adjacent to the active area F-AA. The peripheral area F-NAA may have a color. The peripheral area F-NAA may surround the active area F-AA. Accordingly, a shape of the active area F-AA may be substantially defined by the peripheral area F-NAA. However, this is illustrated as an example, and in another embodiment the peripheral area F-NAA may be disposed adjacent to only one side of the active area F-AA, or may be omitted. The display device ED, according to an embodiment, may include active areas having various shapes, and is not limited to any one embodiment.

In an embodiment, the active area F-AA may include a sensing area EMA. Various electronic modules may be disposed in the sensing area EMA. For example, the electronic modules may include at least one of a camera, a speaker, a light detecting sensor, or a heat detecting sensor. The sensing area EMA may detect an external subject received through the display surface FS, or provide the outside with a sound signal such as voice, through the display surface FS. The electronic module may include a plurality of components, and is not limited to any one embodiment.

In an embodiment, the sensing area EMA may be surrounded by the active area F-AA and the peripheral area F-NAA. However, the invention is not limited thereto. The sensing area EMA may be disposed within the active area F-AA, and is not limited to any one embodiment. FIGS. 1A, etc. illustrate one sensing area EMA as an example, but the number of the sensing area EMA is not limited thereto.

In an embodiment, the sensing area EMA may be a portion of the active area F-AA. Thus, in the display device ED, the sensing area EMA may also display an image. When the electronic modules disposed in the sensing area EMA are inactivated, the sensing area EMA may serve as a display surface to display a video or an image.

In an embodiment, a rear surface RS of the display device ED may be a surface facing the display surface FS. In an embodiment, the rear surface RS may be an outer surface of the display device ED, and not display a video or an image. However, the invention is not limited thereto, and the rear surface RS may function as a second display surface on which a video or an image is displayed. Although not separately illustrated, the display device ED, according to an embodiment, may further include a sensing area disposed on the rear surface RS. A camera, a speaker, a light detecting sensor, or the like may be also disposed in the sensing area on the rear surface RS.

In an embodiment, the display device ED may include a folding area FA and non-folding areas NFA1 and NFA2. The display device ED may include a plurality of non-folding areas NFA1 and NFA2. The display device ED, according to an embodiment, may include a first non-folding area NFA1 and a second non-folding area NFA2 disposed with the folding area FA therebetween. FIGS. 1A to 1C illustrate one embodiment of the display device ED including one folding area FA. However, the invention is not limited thereto, and a plurality of folding areas may be defined in the display device ED. For example, the display device ED, according to an embodiment, may be folded around a plurality of folding axes to be folded so that portions of the display surface FS face each other, and the number of folding axes and the number of the non-folding areas accordingly are not particularly limited.

In an embodiment and referring to FIGS. 1B and 1C, the display device ED may be folded around a folding axis FX extending in one direction. The folding axis FX illustrated in FIGS. 1B and 1C may be a virtual axis extending in the second direction DR2, and the folding axis FX may be parallel to a long side direction of the display device ED. However, the invention is not limited thereto, and an extension direction of the folding axis FX is not limited to the second direction DR2.

In an embodiment, the folding axis FX may extend on the display surface FS in the second direction DR2, or extend below the rear surface RS in the second direction DR2. Referring to FIG. 1B, in an embodiment, the first non-folding area NFA1 and the second non-folding area NFA2 may face each other, and the display device ED may be in-folded so that the display surface FS is not exposed to the outside. Referring to FIG. 1C, the display device ED, according to an embodiment, may be folded around the folding axis FX to be changed into an out-folded state in which one area, which overlaps the first non-folding area NFA1, of the rear surface RS and the other area, which overlaps the second non-folding area NFA2, of the rear surface RS face each other.

In an embodiment, the display device ED may be provided to repeat an operation from a spreading operation to an in-folding or out-folding operation, or vice versa, but an embodiment is not limited thereto. In an embodiment, the display device ED may be provided so as to select any one from the spreading operation, the in-folding operation, and the out-folding operation.

Although FIGS. 1A to 1C illustrate the display device ED folded around the folding axis FX directed parallel to the long side of the display device ED, the invention is not limited thereto, and the display device, according to an embodiment, may be folded around a folding axis directed parallel to a short side of the display device.

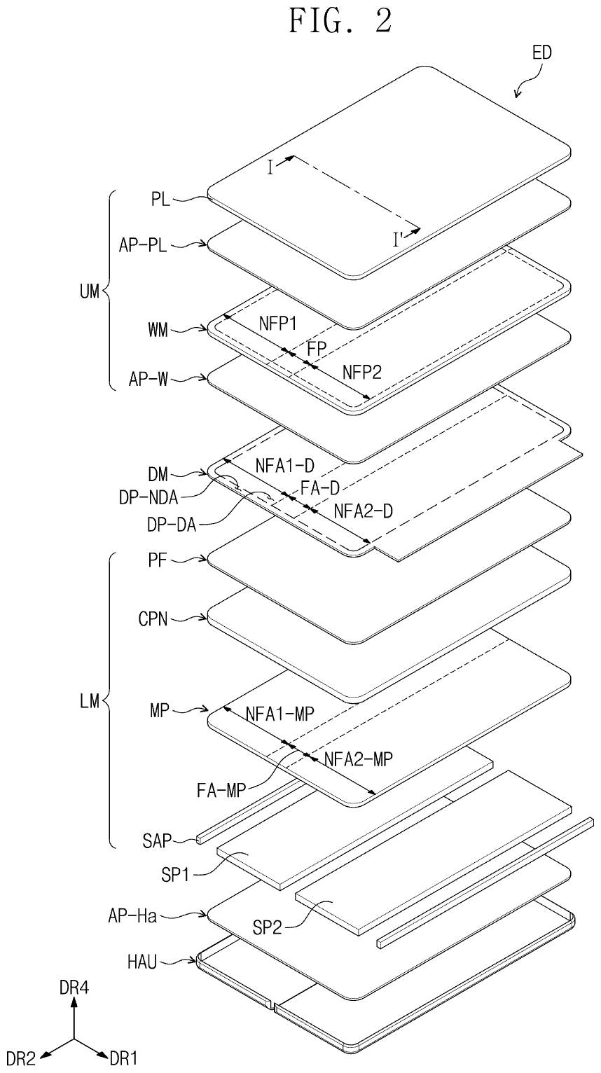

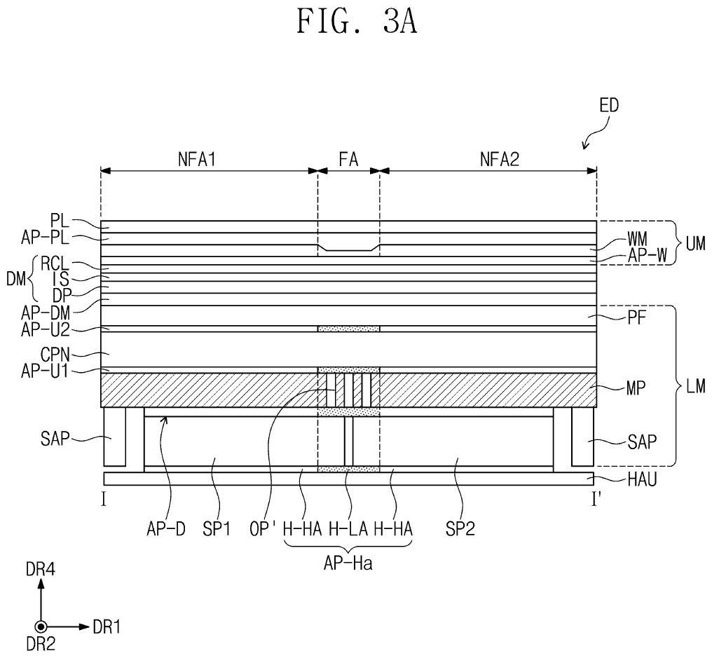

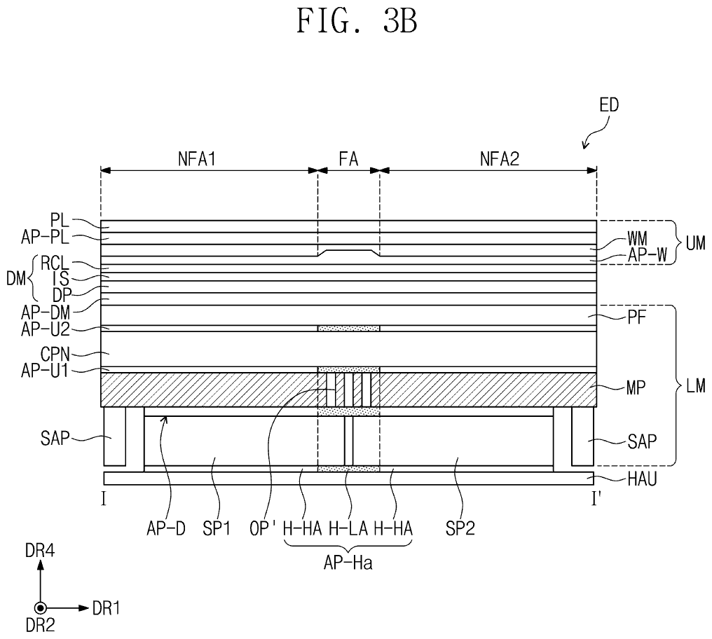

FIG. 2 is an exploded perspective view of a display device, according to an embodiment. FIGS. 3A and 3B are each a cross-sectional view of a display device, according to an embodiment. As an example, FIG. 2 illustrates an exploded perspective view of the display device, according to an embodiment illustrated in FIG. 1A. FIGS. 3A and 3B are each a cross-sectional view illustrating a portion corresponding to line I-I′ in FIG. 2. Unlike the display device illustrated in FIG. 3A, the display device illustrated in FIG. 3B has a concave pattern on a bottom surface of a window.

In an embodiment and referring to FIGS. 2 to 3B together, a display device ED may include a display module DM, an upper module UM disposed above the display module DM, and a lower module LM disposed below the display module DM. In an embodiment, the upper module UM may be referred to as a protective member, and the lower module LM may be referred to as a support member.

In an embodiment, the upper module UM may be disposed above the display module DM and function as a protective part, which protects the display module DM from an external impact or the like, or as an optical part which prevents reflection of external light or improves photo-extraction efficiency.

In an embodiment, the upper module UM may include a window WM disposed above the display module DM, a protective layer PL disposed above the window WM, and a protective layer adhesive layer AP-PL disposed the window WM and the protective layer PL.

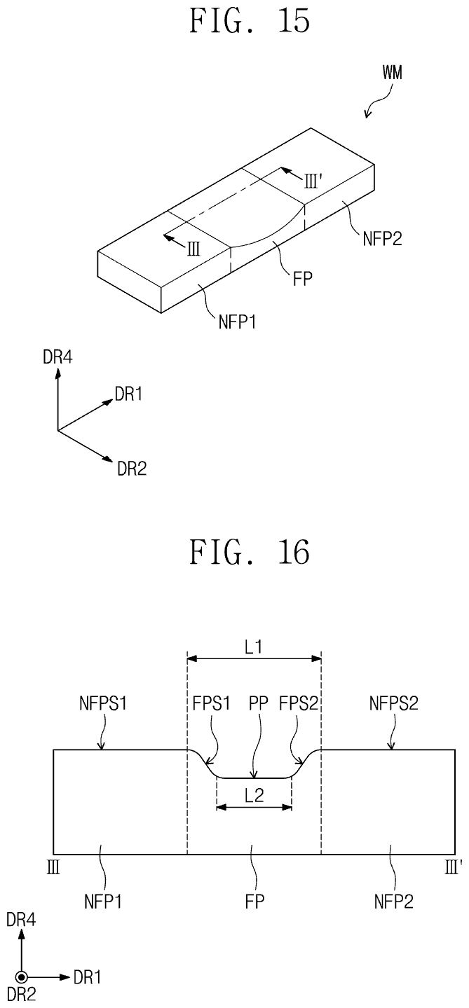

In an embodiment, the window WM may cover the entirety of an outer side of the display module DM. The window WM may have a shape corresponding to a shape of the display module DM. The window WM of the display device ED, according to an embodiment, may include an optically transparent insulation material. The window WM may be a glass substrate or a polymer substrate. For example, the window WM may be a tempered glass substrate undergone a strengthening treatment. In the window WM, according to an embodiment, a stepped portion between a folding portion FP corresponding to a folding area FA and each of non-folding portions NFP1 and NFP2 corresponding to non-folding areas NFA1 and NFA2 may be provided to contribute to a folding characteristic of the display device ED. The stepped portion between the folding portion FP and each of the non-folding portions NFP1 and NFP2 of the window WM may be provided to be disposed adjacent to the protective layer PL as illustrated in FIG. 3A or provided to be disposed adjacent to the display module DM as illustrated in FIG. 3B. A boundary between the folding portion FP and each of the non-folding portions NFP1 and NFP2 of the window WM, according to an embodiment, may be provided to be curved, thereby improving a phenomenon in which the boundary between the folding portion FP and each of the non-folding portions NFP1 and NFP2 of the display device ED is clearly perceived. The detailed shape of the window WM will be described later with reference to FIG. 15.

In an embodiment, the upper module UM may further include a window adhesive layer AP-W disposed below the window WM. The window adhesive layer AP-W may be disposed between the display module DM and the window WM. The window adhesive layer AP-W may be an optically clear adhesive (OCA) film or an optically clear adhesive resin (OCR) layer. In an embodiment, the window adhesive layer AP-W may be omitted.

In an embodiment, the protective layer PL may be disposed above the window WM and protect the window WM from an external environment. The protective layer PL may be transparent, and even when the protective layer PL is disposed, image information provided from the display module DM may be confirmed. The protective layer PL may be exposed as the uppermost surface of the display device ED, and the protective layer PL may be damaged as the display device ED is used.

In an embodiment, the protective layer PL may have optical properties which are a haze value of less than about 1% and a transmittance of about 90% or more in a visible light region. The protective layer PL may include a polymer film. The protective film PL may include the polymer film as a base layer, and further include a functional layer such as a hard coating layer, an anti-fingerprint coating layer, and an anti-static coating layer, on the base layer. The protective layer PL used in the display device ED, according to an embodiment, may have flexibility.

In an embodiment, the protective layer PL may be a polymer film including at least one polymer resin of polyethyleneterephthalte (PET), poly(butylene terephthalate) (PBT), polyethylene Naphthalene (PEN), polycarbonate (PC), poly(methylmethacrylate) (PMMA), Polystyrene (PS), polyvinylchloride (PVC), polyethersulfone (PES), polypropylene (PP), polyamide (PA), modified polyphenylene ether (m-PPO), polyoxymethylene (POM), polysulfone (PSU), polyphenylene sulfide (PPS), polyimide (PI), polyethyleneimine (PEI), polyether ether ketone (PEEK), polyamide imide (PAI), polyarylate (PAR), or thermoplastic polyurethane (TPU).

For example, the protective layer PL, according to an embodiment, may be a polyethyleneterephthalte (PET) film or a thermoplastic polyurethane (TPU) film. The protective layer PL may be a PET film without phase retardation.

In an embodiment, in the display device ED, the protective layer adhesive layer AP-PL may be disposed between the window WM and the protective layer PL. The protective layer adhesive layer AP-PL may be an optically clear adhesive layer. The protective layer adhesive layer AP-PL may be attached to the window WM and fix the protective layer PL to the window WM.

In an embodiment, the display device ED may further include a housing HAU which accommodate the display module DM and the lower module LM. The housing HAU may be coupled to the window WM. In addition, the housing HAU may include a hinge structure for easily folding or bending. The hinge structure may be disposed to corresponding to the folding area FA.

In an embodiment, the display device EDmay include a housing adhesive layer AP-Ha. The housing adhesive layer AP-Ha may function to fix the lower module LM to the housing HAU. The housing adhesive layer AP-Ha may include a folding adhesive portion H-LA corresponding to the folding area FA, and non-folding adhesive portions H-HA corresponding to the non-folding areas NFA1 and NFA2. The housing adhesive layer AP-Ha may be an adhesive member which couples the lower module LM and the housing HAU to each other, and also function as an electromagnetic shielding layer or a heat dissipating layer.

In an embodiment, the display module DM included in the display device ED may be a component that generates an image and detects an input applied from the outside. The display module DM, according to an embodiment, may include a display panel DP, and an input sensor IS disposed on the display panel DP. The display module DM, according to an embodiment, may further include an optical layer RCL disposed on the input sensor IS.

In an embodiment, the display panel DP may be a component that substantially generates an image. The display panel DP may be an emissive display panel, and for example, the display panel DP may be an organic light emitting display panel, an inorganic light emitting display panel, a quantum dot display panel, a micro-LED display panel, or a nano LED display panel. The display panel DP may be referred to as a display layer.

In an embodiment, the input sensor IS may be disposed on the display panel DP. The input sensor IS may detect an external input applied from the outside. The external input may be a user's input. The user's input may include various types of external inputs such as part of the user's body, light, heat, pen, or pressure.

In an embodiment, the input sensor IS may be formed on the display panel DP through a continuous process. In this case, the input sensor IS may be referred to as being directly disposed on the display panel DP. The phrase “being directly disposed” may mean that a third component is not disposed between the input sensor IS and the display panel DP. That is, a separate adhesive member may not be disposed between the input sensor IS and the display panel DP. In another embodiment, the input sensor IS may be coupled to the display panel DP through an adhesive member. The adhesive member may include a general adhesive or adhesive agent.

In an embodiment, the optical layer RCL may be disposed on the input sensor IS. The optical layer RCL may be an anti-reflective layer that reduces reflectance of external light incident from the outside of the display module DM. The optical layer RCL may be formed on the input sensor IS through a continuous process. The optical layer RCL may include a polarizing plate, or include a color filter layer. In another embodiment, the optical layer RCL may include a pigment, a dye, or the like, and absorb light in a specific wavelength range. In a case in which the optical layer RCL includes a color filter layer. the color filter layer may include a plurality of color filters disposed in a predetermined array. For example, the color filters may be arranged considering emissive colors of pixels included in the display panel DP. The optical layer RCL may further include a division pattern which divides the pixels or the like of the display panel DP. The division pattern may include a black pigment or dye. In an embodiment, the optical layer RCL may be omitted.

In an embodiment, the display module DM may be defined as a display area DP-DA and a non-display area DP-NDA. The display area DP-AA may be defined as an area which emits an image provided in the display module DM.

In an embodiment, the non-display area DP-NDA is disposed adjacent to the display area DP-DA. For example, the non-display area DP-NDA may surround the display area DP-DA. However, this is illustrated as an example, and the non-display area DP-NDA may be defined to have various shapes, and is not limited to any one embodiment. According to an embodiment, the display area DP-DA of the display module DM may correspond to at least a portion of the active area F-AA (see FIG. 1A).

In the display device ED, according to an embodiment, the display module DM may include a folding display portion FA-D and non-folding display portions NFA1-D and NFA2-D. The folding display portion FA-D may be a portion corresponding to the folding area FA (see FIG. 1A), and the non-folding display portions NFA1-D and NFA2-D may be portions corresponding to the non-folding areas NFA1 and NFA2 (see FIG. 1A).

In an embodiment, the folding display portion FA-D may correspond to a portion folded or bent around the folding axis FX (see FIG. 1B). The display module DM may include a first non-folding display portion NFA1-D and a second non-folding display portion NFA2-D, and the first non-folding display portion NFA1-D and the second non-folding display portion NFA2-D may be spaced apart from each other with the folding display portion FA-D therebetween.

The display device ED, according to an embodiment, may further include a module adhesive layer AP-DM disposed between the display module DM and the lower module LM. The module adhesive layer AP-DM may be an optically clear adhesive (OCA) film or an optically clear adhesive resin (OCR) layer.

In the display device ED, according to an embodiment, the lower module LM may include a support plate MP and adhesive layers AP-U1, AP-U2 and AP-D disposed above and below the support plate MP. In an embodiment, the lower module LM may further include at least one of supports SP1 and SP2, a filling part SAP, a module protective layer PF, or a buffer layer CPN. For example, the display device ED according to an embodiment may include the support plate MP disposed below the display module DM, the module protective layer PF and the buffer layer CPN which are disposed between the support plate MP and the display module DM, and the supports SP1 and SP2 and the filling part SAP which are disposed below the support plate MP.

In an embodiment, the support plate MP may be disposed below the display module DM. The support plate MP may include a folding support portion FA-MP and non-folding support portions NFA1-MP and NFA2-MP. In the present disclosure, the folding support portion FA-MP may be referred to as a folding portion, and the non-folding support portions NFA1-MP and NFA2-MP may be referred to as non-folding portions. A first non-folding folding portion NFA1-MP and a second non-folding portion NFA2-MP of the support plate MP may be spaced apart from each other with the folding portion FA-MP therebetween. The folding portion FA-MP may be a portion corresponding to the folding area FA, and the non-folding portions NFA1-MP and NFA2-MP may be portions corresponding to the non-folding areas NFA1 and NFA2.

In an embodiment, the support plate MP may include a metal material or a polymer material. For example, the support plate MP may include stainless steel, aluminum, or an alloy thereof. In another embodiment, the support plate MP may be made of carbon fiber reinforced plastic (CFRP) or the like. However, the invention is not limited thereto, and the support plate MP may include at least one of a non-metal material, plastic, glass fiber reinforced plastic, or glass.

A plurality of opening portions OP′ may be defined in the support plate MP. The opening portions OP′ may be defined to correspond to the folding area FA.

In an embodiment, the module protective layer PF may be disposed between the display module DM and the support plate MP. The module protective layer PF may be a layer that is disposed below the display module DM and protects a rear surface of the display module DM. The module protective layer PF may overlap the entirety of the display module DM. The module protective layer PF may include a polymer material. For example, the module protective layer PF may be a polyimide film or a polyethylene terephthalate film. However, this is merely illustrative, and the material of the module protective layer PF is not limited thereto.

In an embodiment, the display device ED may include the supports SP1 and SP2 and the filling part SAP. The supports SP1 and SP2 may be portions overlapping most of an area of the display module DM. The filling part SAP may be a portion disposed outside each of the supports SP1 and SP2 and overlapping an outer edge of the display module DM.

In an embodiment, the supports SP1 and SP2 may include a first sub-support SP1 and a second sub-support SP2 that are spaced apart from each other in the first direction DR1. The first sub-support SP1 and the second sub-support SP2 may be spaced apart from each other at a portion corresponding to the folding axis FX (see FIG. 1B). The supports SP1 and SP2 may be spaced apart from each other in the folding area FA and provided as the first sub-support SP1 and the second sub-support SP2, thereby improving the folding or bending characteristic of the display device ED. Although not illustrated, the lower module LM may further include a cushion layer (not illustrated) stacked above or below the supports SP1 and SP2. The cushion layer (not illustrated) may include sub-cushion layers separated from each other at a portion corresponding to the folding axis FX (see FIG. 1B). A lower adhesive layer, in which adhesion of a portion corresponding to the folding area FA is less than adhesion of a portion corresponding to each of the non-folding areas NFA1 and NFA2, may be further disposed between the supports SP1 and SP2 and the cushion layer (not illustrated).

In an embodiment, the cushion layer (not illustrated) may prevent the support plate MP from being pressed or deformed due to an external impact and force. The cushion layer (not illustrated) may include an elastomer such as sponge, foam, or urethane resin. The cushion layer (not illustrated) may include at least one of an acrylic polymer, a urethane-based polymer, a silicon-based polymer, or an imide-based polymer. However, the invention is not limited thereto. The cushion layer (not illustrated) may be disposed below the support plate MP or below a lower support plate (not illustrated).

In an embodiment, the filling part SAP may be disposed outside the supports SP1 and SP2. The filling part SAP may be disposed between the support plate MP and the housing HAU. The filling part SAP may fill a space between the support plate MP and the housing HAU, and fix the support plate MP.

In the display device ED, according to an embodiment, the lower module LM may include the buffer layer CPN. The buffer layer CPN may serve as a thickness compensating layer which compensates a thickness of the lower side of the display module DM, or a support layer which supports the display module DM. Unlike the illustrated embodiment, the buffer layer CPN may be omitted in another embodiment.

In the display device ED, according to an embodiment, a combination of the components included in the lower module LM is not limited to the configuration illustrated or described herein, and the combination may be changed according to the size or shape of the display device ED, or the operation characteristics of the display device ED. For example, the lower module LM may further include an additional component such as a support plate, a cushion member, or an adhesive layer.

In the display device ED, according to an embodiment, the lower module LM may include one or more upper adhesive layers AP-U1 and AP-U2 disposed above the support plate MP, and at least one lower adhesive layer AP-D disposed below the support plate MP.

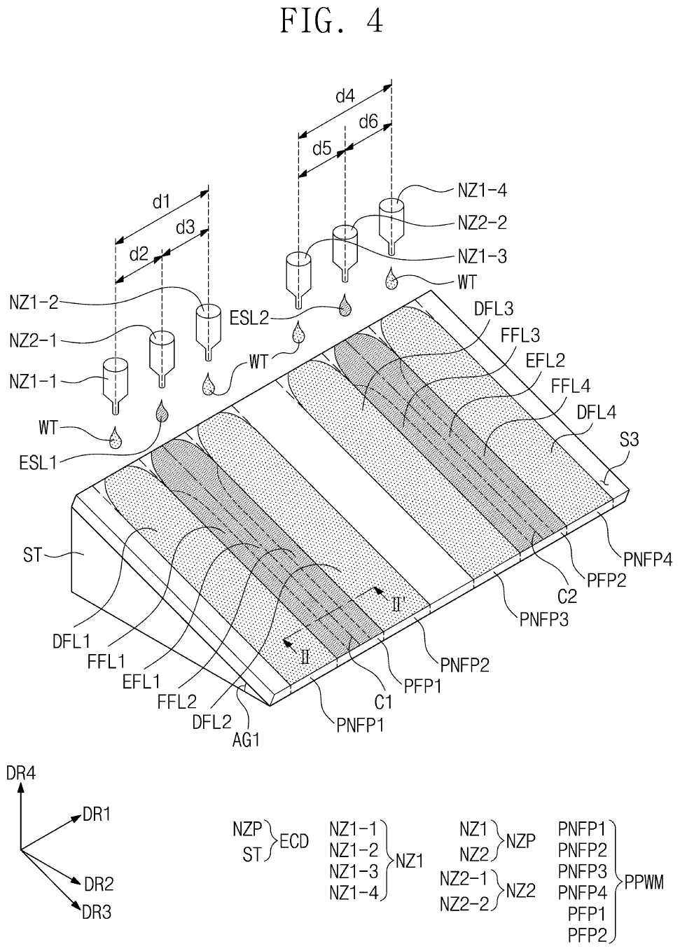

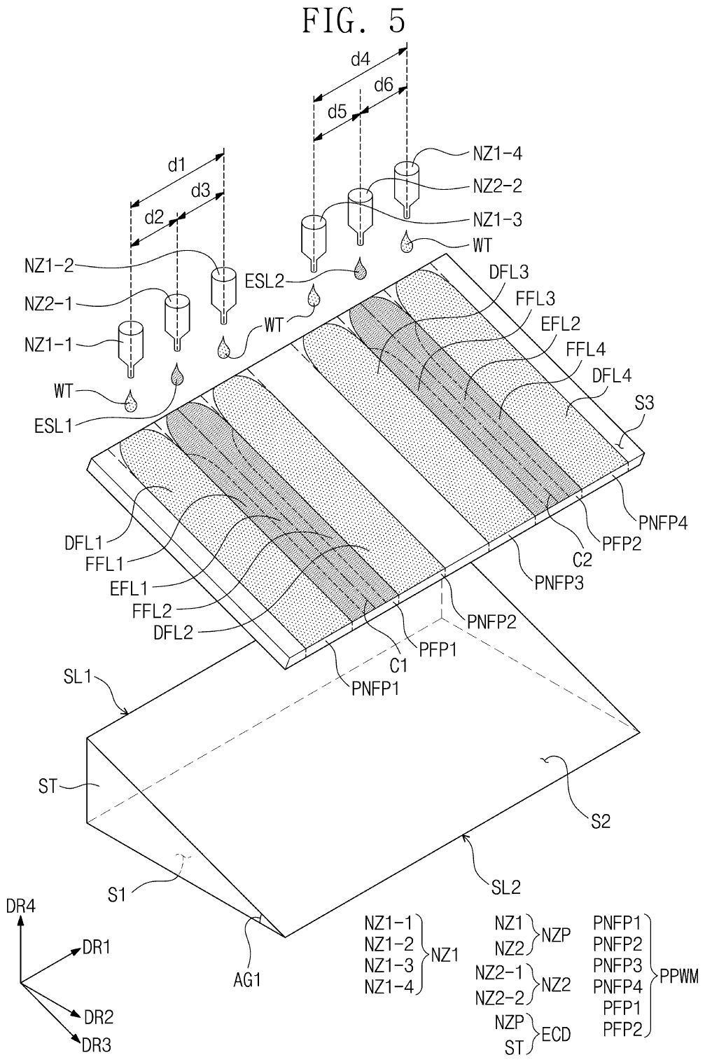

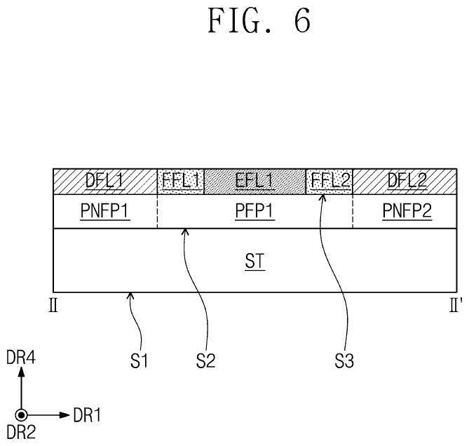

FIG. 4 is a perspective view of an etching device, according to an embodiment. FIG. 5 is an exploded perspective view of an etching device, according to an embodiment. An etching device ECD is a device for manufacturing the window WM described above with reference to FIG. 2. FIG. 6 illustrates a cross-section of the etching device ECD illustrated in FIG. 4, according to an embodiment. FIG. 6 illustrates a state in which a fluid is formed on a top surface of a target substrate PPWM disposed on the etching device ECD in FIG. 4.

Referring to FIGS. 4 and 5, the etching device ECD, according to an embodiment, includes a stage ST and a nozzle part NZP.

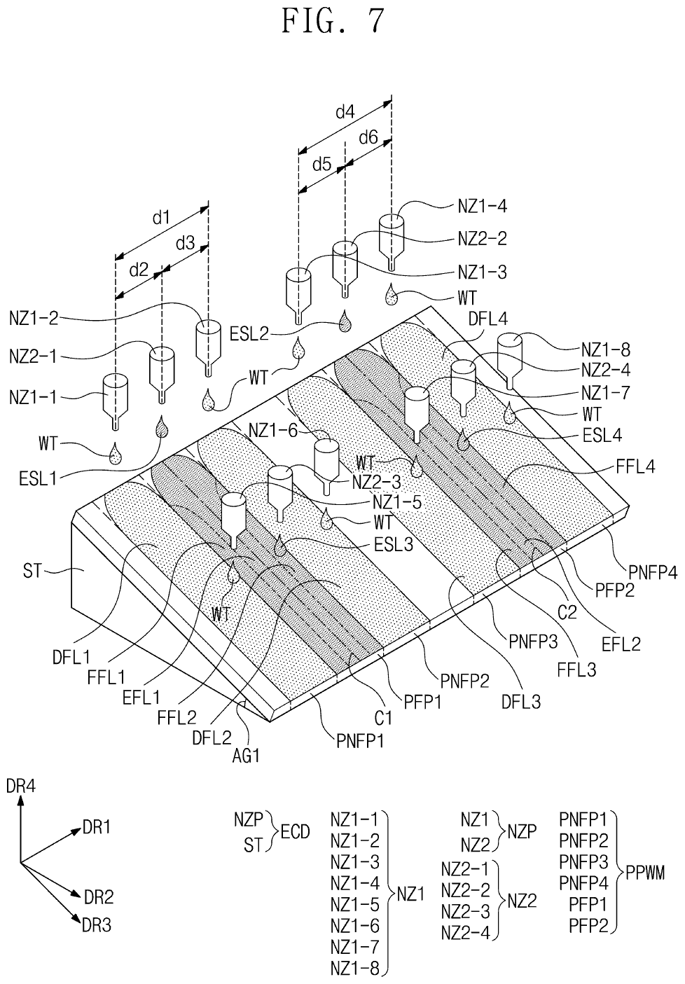

In an embodiment, the target substrate PPWM is disposed on the stage ST. The stage ST may provide a base surface to which the target substrate PPWM is fixed. The stage ST may include an acid-resistant material. The acid-resistant material may include plastic. The stage ST may be made of plastic. The stage ST may not be corroded by first to fourth etchants ESL1, ESL2, ESL3 and ESLA (see FIG. 7) to be described later. Unlike the embodiment illustrated in FIG. 4, the stage ST may be larger than a surface area of the target substrate PPWM on a plane. According to use of the etching device ECD, according to an embodiment, the target substrate PPWM may be the window WM (see FIG. 2) described above.

In an embodiment, the stage ST includes a first surface S1 parallel to a plane defined by a first direction DR1 and a second direction DR2 crossing the first direction DR1, and a second surface S2 directed parallel to a third direction DR3 which forms a first angle AG1 with the second direction DR2.

In an embodiment, the first surface S1 may be defined as a lower surface or bottom surface of the stage ST. The second surface S2 may be defined as an inclined surface of the stage ST. An angle formed between the first surface S1 and the second surface S2 may be the first angle AG1. The first angle AG1 may be about 1° to about 10°. For example, the first angle AG1 may be about 1°. When the first angle AG1 is less than about 1°, deionized water WT and the first etchant ESL1 may not sufficiently flow in the third direction DR3, and thus efficiency of the etching device ECD may be decreased. When the first angle AG1 is more than about 10°, the deionized water WT and the first etchant ESL1 may excessively fast flow in the third direction DR3, and thus enough time to etch the target substrate PPWM may not be provided.

In an embodiment, the second surface S2 may provide a base surface on which the target substrate PPWM is seated. The second surface S2 includes a first side SL1 directed parallel to the first direction DR1, and a second side SL2 opposing the first side SL1 in the third direction DR3 and disposed adjacent to the first surface S1. The first surface S1 and the second surface S2 may cross each other while sharing the second side SL2.

In an embodiment, the nozzle part NZP includes a first nozzle NZ1 and a second nozzle NZ2. The first nozzle NZ1 includes a (1-1)-th nozzle NZ1-1 and a (1-2)-th nozzle NZ1-2 spaced apart from the (1-1)-th nozzle NZ1-1 in the first direction DR1. The second nozzle NZ2 includes a (2-1)-th nozzle NZ2-1 disposed between the (1-1)-th nozzle NZ1-1 and the (1-2)-th nozzle NZ1-2. Each of the (1-1)-th nozzle NZ1-1 and the (1-2)-th nozzle NZ1-2 provides the deionized water WT toward the first side SL1. The (2-1)-th nozzle NZ2-1 provides the first etchant ESL1 toward the first side SL1. The first etchant ESL1 may include a fluorine-containing compound. For example, the first etchant ESL1 may include hydrofluoric acid or ammonium bifluoride.

In an embodiment, a distance d1 by which the (1-1)-th nozzle NZ1-1 and the (1-2)-th nozzle NZ1-2 are spaced apart from each other in the first direction DR1 may be about 1 mm to about 30 mm. For example, the distance d1 by which the (1-1)-th nozzle NZ1-1 and the (1-2)-th nozzle NZ1-2 are spaced apart from each other in the first direction DR1 may be about 30 mm. A distance d2 by which the (1-1)-th nozzle NZ1-1 and the (2-1)-th nozzle NZ2-1 are spaced apart from each other in the first direction DR1, and a distance d3 by which the (2-1)-th nozzle NZ2-1 and the (1-2)-th nozzle NZ1-2 are spaced apart from each other in the first direction DR1, may be each independently about 0.5 mm to about 15 mm. For example, the distance d2 by which the (1-1)-th nozzle NZ1-1 and the (2-1)-th nozzle NZ2-1 are spaced apart from each other in the first direction DR1, and the distance d3 by which the (2-1)-th nozzle NZ2-1 and the (1-2)-th nozzle NZ1-2 are spaced from each other in the first direction DR1, may each be about 15 mm. The distance d2 by which the (1-1)-th nozzle NZ1-1 and the (2-1)-th nozzle NZ2-1 are spaced apart from each other in the first direction DR1, and the distance d3 by which the (2-1)-th nozzle NZ2-1 and the (1-2)-th nozzle NZ1-2 are spaced apart from each other in the first direction DR1, may be substantially the same.

In an embodiment, the first nozzle NZ1 may further include a (1-3)-th nozzle NZ1-3 spaced apart from the (1-2)-th nozzle NZ1-2 in the first direction DR1, and a (1-4)-th nozzle NZ1-4 spaced apart from the (1-3)-th nozzle NZ1-3 in the first direction DR1. The second nozzle NZ2 may further include a (2-2)-th nozzle NZ2-2 disposed between the (1-3)-th nozzle NZ1-3 and the (1-4)-th nozzle NZ1-4. Each of the (1-3)-th nozzle NZ1-3 and the (1-4)-th nozzle NZ1-4 provides the deionized water WT toward the first side SL1. The (2-2)-th nozzle NZ2-2 provides the second etchant ESL2 toward the first side SL1. The second etchant ESL2 may include a fluorine-containing compound. For example, the second etchant ESL2 may include hydrofluoric acid or ammonium bifluoride.

In an embodiment, a distance d4 by which the (1-3)-th nozzle NZ1-3 and the (1-4)-th nozzle NZ1-4 are spaced apart from each other in the first direction DR1 may be about 1 mm to about 30 mm. For example, the distance d4 by which the (1-3)-th nozzle NZ1-3 and the (1-4)-th nozzle NZ1-4 are spaced apart from each other in the first direction DR1 may be about 30 mm. A distance d5 by which the (1-3)-th nozzle NZ1-3 and the (2-2)-th nozzle NZ2-2 are spaced apart from each other in the first direction DR1, and a distance d6 by which the (2-2)-th nozzle NZ2-2 and the (1-4)-th nozzle NZ1-4 are spaced apart from each other in the first direction DR1, may be each independently about 0.5 mm to about 15 mm. For example, the distance d5 by which the (1-3)-th nozzle NZ1-3 and the (2-2)-th nozzle NZ2-2 are spaced apart from each other in the first direction DR1, and the distance d6 by which the (2-2)-th nozzle NZ2-2 and the (1-4)-th nozzle NZ1-4 are spaced apart from each other in the first direction DR1, may each be about 15 mm. The distance d5 by which the (1-3)-th nozzle NZ1-3 and the (2-2)-th nozzle NZ2-2 are spaced apart from each other in the first direction DR1, and the distance d6 by which the (2-2)-th nozzle NZ2-2 and the (1-4)-th nozzle NZ1-4 are spaced apart from each other in the first direction DR1, may be substantially the same.

In an embodiment, the target substrate PPWM is disposed on the stage ST. The target substrate PPWM may be directly disposed on the second surface S2. The target substrate PPWM may include mother glass. The target substrate PPWM includes a third surface S3 directed parallel to the third direction DR3. The third surface S3 may be directed parallel to the second surface S2. The third surface S3 may be a top surface of the target substrate PPWM.

In an embodiment, the target substrate PPWM may include a preliminary first non-folding portion PNFP1, a preliminary second non-folding portion PNFP2 spaced apart from the preliminary first non-folding portion PNFP1 on a plane, and a preliminary first folding portion PFP1 disposed between the preliminary first non-folding portion PNFP1 and the preliminary second non-folding portion PNFP2 on a plane. The preliminary first non-folding portion PNFPI may correspond to the first non-folding area NFA1 (see FIG. 1A) described above. The preliminary second non-folding portion PNFP2 may correspond to the second non-folding area NFA2 (see FIG. 1A) described above. The preliminary first folding portion PFP1 may correspond to the folding area FA (see FIG. 1A) described above.

In an embodiment, the target substrate PPWM may include a preliminary third non-folding portion PNFP3, a preliminary fourth non-folding portion PNFP4 spaced apart from the preliminary third non-folding portion PNFP3 on a plane, and a preliminary second folding portion PFP2 disposed between the preliminary third non-folding portion PNFP3 and the preliminary fourth non-folding portion PNFP4 on a plane. The preliminary third non-folding portion PNFP3 may correspond to the first non-folding area NFA1 (see FIG. 1A) described above. The preliminary fourth non-folding portion PNFP4 may correspond to the second non-folding area NFA2 (see FIG. 1A) described above. The preliminary second folding portion PFP2 may correspond to the folding area FA (see FIG. 1A) described above.

In an embodiment and referring to FIGS. 4 and 6 together, each of the (1-1)-th nozzle NZ1-1 and the (1-2)-th nozzle NZ1-2 provides the deionized water WT on the third surface S3. The (1-1)-th nozzle NZ1-1 may provide the deionized water WT on the preliminary first non-folding portion PNFPI to form a first deionized fluid DFL1. The (1-2)-th nozzle NZ1-2 may provide the deionized water WT on the preliminary second non-folding portion PNFP2 to form a second deionized fluid DFL2. The (2-1)-th nozzle NZ2-1 provides the first etchant ESL1 toward the third surface S3. The (2-1)-th nozzle NZ2-1 may provide the first etchant ESL1 on the preliminary first folding portion PFP1 to form a first etching fluid EFL1.

In an embodiment, the first deionized fluid DFL1, the second deionized fluid DFL2, and the first etching fluid EFL1 may each flow in the third direction DR3. A part of the first deionized fluid DFL1 and a part of the first etching fluid EFL1 may be mixed to form a first mixed fluid FFL1 flowing in the third direction DR3. The first mixed fluid FFL1 may be formed between the first deionized fluid DFL1 and the first etching fluid EFL1. A part of the second deionized fluid DFL2 and a part of the first etching fluid EFL1 may be mixed to form a second mixed fluid FFL2 flowing in the third direction DR3. The second mixed fluid FFL2 may be formed between the second deionized fluid DFL2 and the first etching fluid EFL1.

In an embodiment, the etching device ECD, a concentration of a fluorine-containing compound in each of the first mixed fluid FFL1 and the second mixed fluid FFL2 may be less than a concentration of a fluorine-containing compound in the first etching fluid EFL1. When viewed in the first direction DR1, on a basis of a first center C1 that is a virtual line passing through the middle of the first etchant ESL1 and extending in the third direction DR3, the concentration of the fluorine-containing compound included in the fluid gradually decreases toward a boundary between the first deionized fluid DFL1 and the first mixed fluid FFL1 or a boundary between the second deionized fluid DFL2 and the second mixed fluid FFL2. Accordingly, a boundary between a folding portion FP and each of non-folding portions NFP1 and NFP2 of a window WM (see FIG. 15) to be described later may be formed to be curved, thereby improving the reliability of the display device ED (see FIG. 1A).

In an embodiment, each of the (1-3)-th nozzle NZ1-3 and the (1-4)-th nozzle NZ1-4 may provide the deionized water WT on the third surface S3. The (1-3)-th nozzle NZ1-3 may provide the deionized water WT on the preliminary third non-folding portion PNFP3 to form a third deionized fluid DFL3. The (1-4)-th nozzle NZ1-4 may provide the deionized water WT on the preliminary fourth non-folding portion PNFP4 to form a fourth deionized fluid DFLA. The (2-2)-th nozzle NZ2-2 provides the second etchant ESL2 on the third surface S3. The (2-2)-th nozzle NZ2-2 may provide the second etchant ESL2 on the preliminary second folding portion PFP2 to form a second etching fluid EFL2.

In an embodiment, the third deionized fluid DFL3, the fourth deionized fluid DFL4, and the second etching fluid EFL2 may each flow in the third direction DR3. A part of the third deionized fluid DFL3 and a part of the second etching fluid EFL2 may be mixed to form a third mixed fluid FFL3 flowing in the third direction DR3. The third mixed fluid FFL3 may be formed between the third deionized fluid DFL3 and the second etching fluid EFL2. A part of the fourth deionized fluid DFL4 and a part of the second etching fluid EFL2 may be mixed to form a fourth mixed fluid FFLA flowing in the third direction DR3. The fourth mixed fluid FFL4 may be formed between the fourth deionized fluid DFL4 and the second etching fluid EFL2.

In an embodiment, the etching device ECD, a concentration of a fluorine-containing compound in each of the third mixed fluid FFL3 and the fourth mixed fluid FFL4 may be less than a concentration of a fluorine-containing compound in the second etchant ESL2. When viewed in the first direction DR1, on a basis of a second center C2 that is a virtual line passing through the middle of the second etchant ESL2 and extending in the third direction DR3, the concentration of the fluorine-containing compound included in the fluid gradually decreases toward a boundary between the third deionized fluid DFL3 and the third mixed fluid FFL3 or a boundary between the fourth deionized fluid DFL4 and the fourth mixed fluid FFLA. Accordingly, the boundary between the folding portion FP and each of the non-folding portions NFP1 and NFP2 of the window WM (see FIG. 15) to be described later may be formed to be curved, thereby improving the reliability of the display device ED (see FIG. 1A).

FIG. 7 is a perspective view of an etching device, according to an embodiment. Unlike FIG. 4, FIG. 7 illustrates an embodiment in which a (1-5)-th nozzle NZ1-5, a (1-6)-th nozzle NZ1-6, a (2-3)-th nozzle NZ2-3, a (1-7)-th nozzle NZ1-7, a (1-8)-th nozzle NZ1-8, and a (2-4)-th nozzle NZ2-4 are further disposed.

In an embodiment to be described with reference to FIG. 7, the contents about the components described with reference to FIG. 4 may be avoided, and additionally disposed components will be mainly described.

In an embodiment and referring to FIG. 7, a first nozzle NZ1 may further include the (1-5)-th nozzle NZ1-5, the (1-6)-th nozzle NZ1-6, the (1-7)-th nozzle NZ1-7, and the (1-8)-th nozzle NZ1-8. A second nozzle NZ2 may further include the (2-3)-th nozzle NZ2-3 and the (2-4)-th nozzle NZ2-4.

In an embodiment, the (1-5)-th nozzle NZ1-5 may be spaced apart from a (1-1)-th nozzle NZ1-1 in the third direction DR3. The (1-6)-th nozzle NZ1-6 may be spaced apart from a (1-2)-th nozzle NZ1-2 in the third direction DR3. The (1-5)-th nozzle NZ1-5 may provide deionized water WT on a preliminary first non-folding portion PNFP1 to form a first deionized fluid DFL1 together with the deionized water WT provided through the (1-1)-th nozzle NZ1-1. The (1-6)-th nozzle NZ1-6 may provide the deionized water WT on a preliminary second non-folding portion PNFP2 to form a second deionized fluid DFL2 together with the deionized water WT provided through the (1-2)-th nozzle NZ1-2.

In an embodiment, the (2-3)-th nozzle NZ2-3 may be spaced apart from a (2-1)-th nozzle NZ2-1 in the third direction DR3. The (2-3)-th nozzle NZ2-3 may provide a third etchant ESL3 on a preliminary first folding portion PFP1 to form a first etching fluid EFL1 together with a first etchant ESL1 provided through the (2-1)-th nozzle NZ2-1.

In an embodiment, the (1-7)-th nozzle NZ1-7 may be spaced apart from a (1-3)-th nozzle NZ1-3 in the third direction DR3. The (1-8)-th nozzle NZ1-8 may be spaced apart from a (1-4)-th nozzle NZ1-4 in the third direction DR3. The (1-7)-th nozzle NZ1-7 may provide the deionized water WT on a preliminary third non-folding portion PNFP3 to form a third deionized fluid DFL3 together with the deionized water WT provided through the (1-3)-th nozzle NZ1-3. The (1-8)-th nozzle NZ1-8 may provide the deionized water WT on a preliminary fourth non-folding portion PNFP4 to form a fourth deionized fluid DFL4 together with the deionized water WT provided through the (1-4)-th nozzle NZ1-4.

In an embodiment, the (2-4)-th nozzle NZ2-4 may be spaced apart from a (2-2)-th nozzle NZ2-2 in the third direction DR3. The (2-4)-th nozzle NZ2-4 may provide a fourth etchant ESLA on a preliminary second folding portion PFP2 to form a second etching fluid EFL2 together with a second etchant ESL2 provided through the (2-2)-th nozzle NZ2-2.

As the etching device ECD, according to an embodiment, further includes the (1-5)-th nozzle NZ1-5, the (1-6)-th nozzle NZ1-6, the (2-3)-th nozzle NZ2-3, the (1-7)-th nozzle NZ1-7, the (1-8)-th nozzle NZ1-8, and the (2-4)-th nozzle NZ2-4, each of the first mixed fluid FFL1, the first etching fluid EFL1, the second mixed fluid FFL2, the third mixed fluid FFL3, the second etching fluid EFL2 and the fourth mixed fluid FFL4 may be increased in flow rate to smoothly flow in the third direction DR3.

Hereinafter, a method for manufacturing a window using the above-described etching device, according to an embodiment, will be described, and details of the components described with reference to FIGS. 1A to 7 may be avoided.

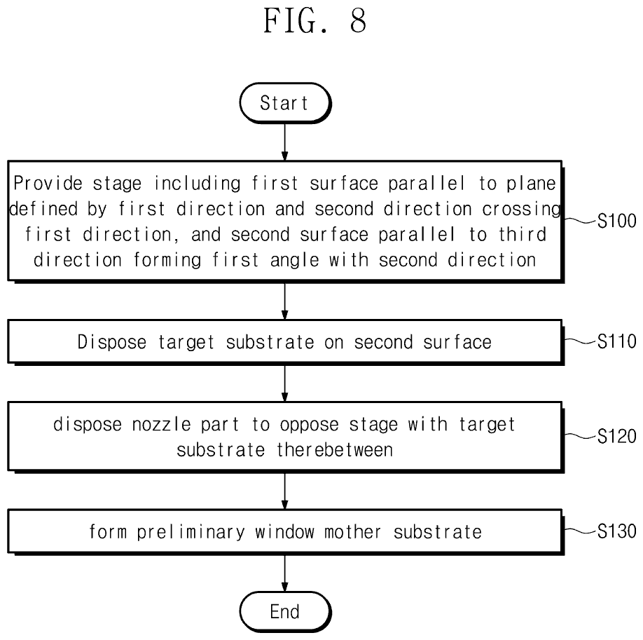

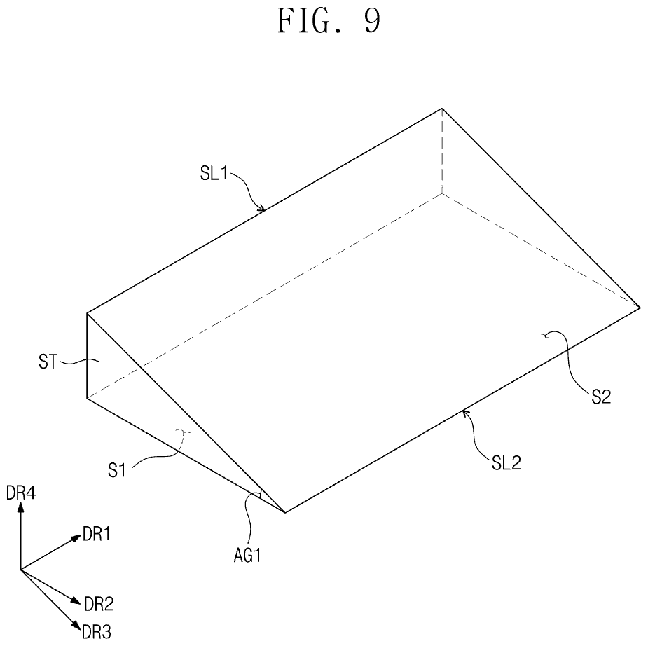

FIG. 8 is a flowchart of a method for manufacturing a window, according to an embodiment. FIGS. 9 to 14 are views illustrating some of a method for manufacturing a window, according to an embodiment.

In an embodiment and referring to FIG. 8, the method for manufacturing the window includes providing a stage including a first surface parallel to a plane defined by a first direction and a second direction crossing the first direction, and a second surface parallel to a third direction which forms a first angle with the second direction (S100), disposing a target substrate on the second surface (S110), disposing a nozzle part so as to oppose the stage with the target substrate therebetween (S120), and forming a preliminary window mother substrate (S130).

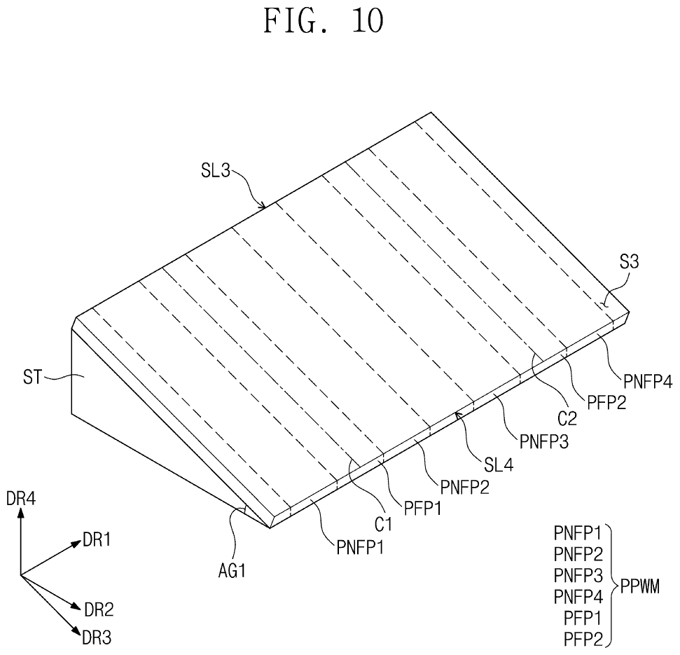

In an embodiment and referring to FIGS. 9 and 10 together, in the providing of a stage ST, the stage ST may be disposed such that a first surface S1 is a bottom surface. In the disposing of a target substrate PPWM on a second surface S2, the target substrate PPWM may be directly disposed on the second surface S2. A third surface S3 included by the target substrate PPWM includes a third side SL3 parallel to the first direction DR1, and a fourth side SLA opposing the third side SL3 in the third direction DR3 and adjacent to the first surface S1.

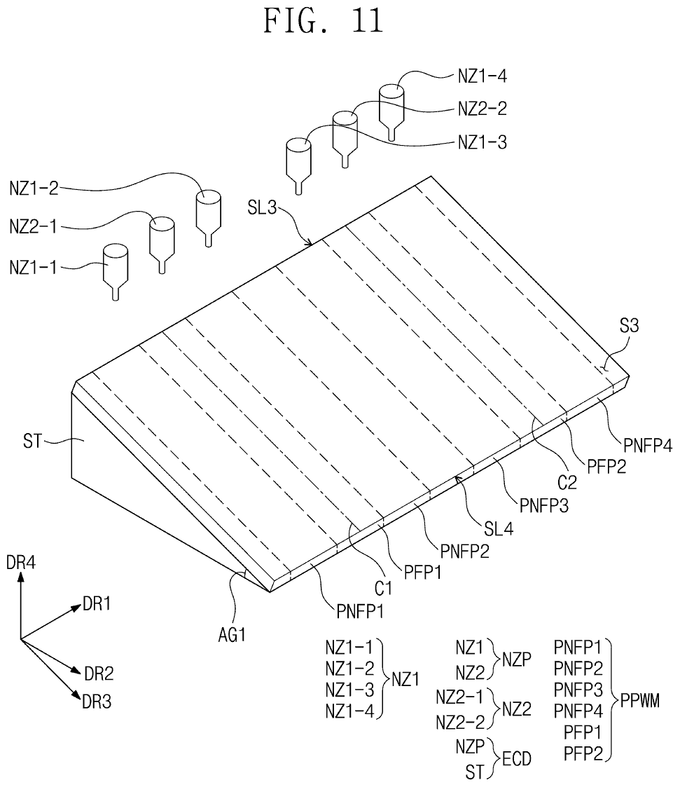

In an embodiment and referring to FIG. 11, in the disposing of a nozzle part NZP so as to oppose the stage ST with the target substrate PPWM therebetween, each of a (1-1)-th nozzle NZ1-1, a (1-2)-th nozzle NZ1-2, a (1-3)-th nozzle NZ1-3, a (1-4)-th nozzle NZ1-4, a (2-1)-th nozzle NZ2-1, and a (2-2)-th nozzle NZ2-2, which are included by the nozzle part NZP, is disposed adjacent to the third side SL3. Unlike the illustrated embodiment, each of the (1-1)-th nozzle NZ1-1, the (1-2)-th nozzle NZ1-2, the (1-3)-th nozzle NZ1-3, the (1-4)-th nozzle NZ1-4, the (2-1)-th nozzle NZ2-1, and the (2-2)-th nozzle NZ2-2 may be disposed such that an outlet faces the third direction DR3.

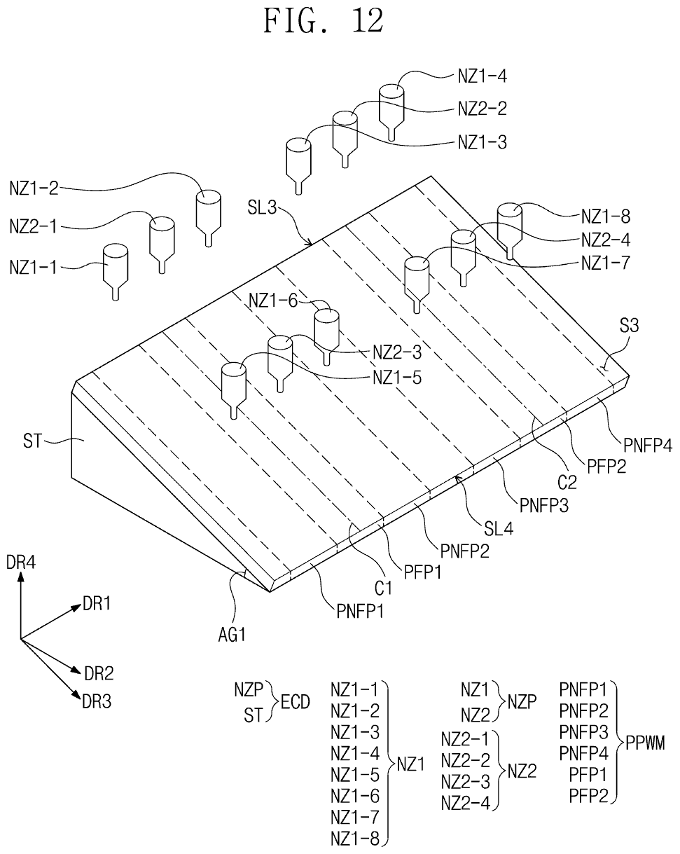

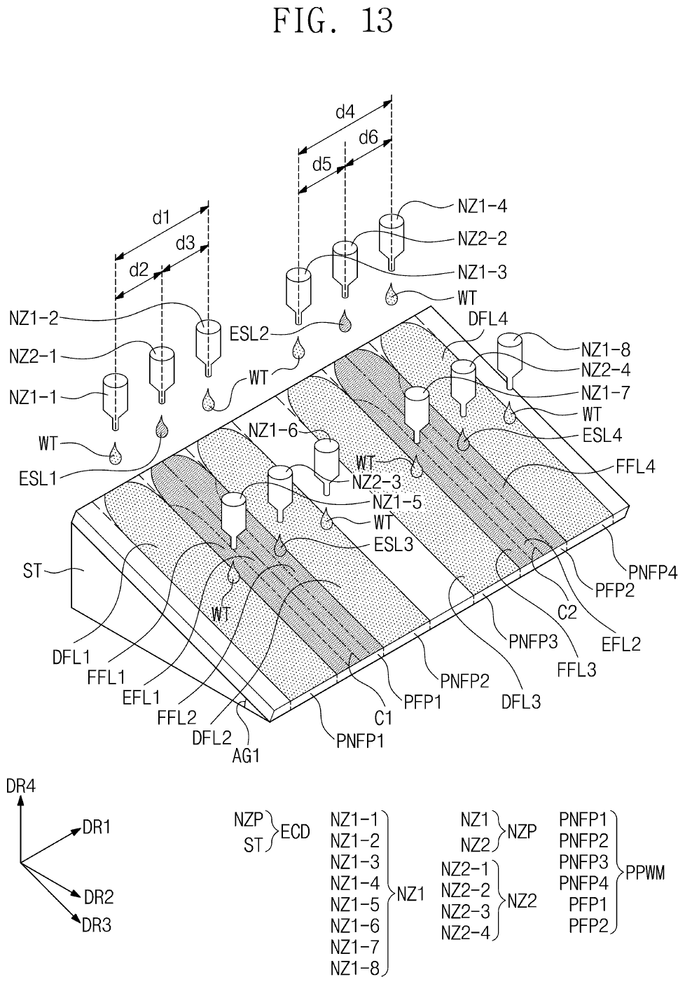

In an embodiment and referring to FIGS. 12 and 13 together, unlike FIG. 11, a (1-5)-th nozzle NZ1-5, a (1-6)-th nozzle NZ1-6, a (1-7)-th nozzle NZ1-7, a (1-8)-th nozzle NZ1-8, a (2-3)-th nozzle NZ2-3, and a (2-4)-th nozzle NZ2-4 may be further disposed. The (1-5)-th nozzle NZ1-5, the (1-6)-th nozzle NZ1-6, the (1-7)-th nozzle NZ1-7, the (1-8)-th nozzle NZ1-8, the (2-3)-th nozzle NZ2-3, and the (2-4)-th nozzle NZ2-4 may be sequentially arranged in the first direction DR1.

In an embodiment, deionized water WT provided on a preliminary first non-folding portion PNFP1 through each of the (1-1)-th nozzle NZ1-1 and the (1-5)-th nozzle NZ1-5 may form a first deionized fluid DFL1 flowing in the third direction DR3. A first etchant ESL1 provided on a preliminary first folding portion PFP1 through the (2-1)-th nozzle NZ2-1 may flow in the third direction DR3, and be mixed with a third etchant ESL3 provided on the preliminary first folding portion PFP1 through the (2-3)-th nozzle NZ2-3 to form a first etching fluid EFL1. A part of the first deionized fluid DFL1 and a part of the first etching fluid EFL1 may be mixed to form a first mixed fluid FFL1 flowing in the third direction DR3.

In an embodiment, the deionized water WT provided on a preliminary second non-folding portion PNFP2 through each of the (1-2)-th nozzle NZ1-2 and the (1-6)-th nozzle NZ1-6 may form a second deionized fluid DFL2 flowing in the third direction DR3. A part of the second deionized fluid DFL2 and a part of the first etching fluid EFL1 may be mixed to form a second mixed fluid FFL2 flowing in the third direction DR3.

In an embodiment, the deionized water WT provided on a preliminary third non-folding portion PNFP3 through each of the (1-3)-th nozzle NZ1-3 and the (1-7)-th nozzle NZ1-7 may form a third deionized fluid DFL3 flowing in the third direction DR3. A second etchant ESL2 provided on a preliminary second folding portion PFP2 through the (2-2)-th nozzle NZ2-2 may flow in the third direction DR3, and be mixed with a fourth etchant ESL4 provided on the preliminary second folding portion PFP2 through the (2-4)-th nozzle NZ2-4 to form a second etching fluid EFL2. A part of the third deionized fluid DFL3 and a part of the second etching fluid EFL2 may be mixed to form a third mixed fluid FFL3 flowing in the third direction DR3.

In an embodiment, the deionized water WT provided on a preliminary fourth non-folding portion PNFP4 through each of the (1-4)-th nozzle NZ1-4 and the (1-8)-th nozzle NZ1-8 may form a fourth deionized fluid DFL4 flowing in the third direction DR3. A part of the fourth deionized fluid DFL4 and a part of the second etching fluid EFL2 may be mixed to form a fourth mixed fluid FFLA flowing in the third direction DR3.

In an embodiment, a concentration of a fluorine-containing compound included in each of the first mixed fluid FFL1 and the second mixed fluid FFL2 may be less than a concentration of a fluorine-containing compound included in the first etching fluid EFL1, and a concentration of a fluorine-containing compound included in each of the third mixed fluid FFL3 and the fourth mixed fluid FFLA may be less than a concentration of a fluorine-containing compound included in the second etching fluid EFL2. Accordingly, each of a boundary between a first non-folding portion NFP1 and a folding portion FP and a boundary between a second non-folding portion NFP2 and the folding portion FP of a window WM (see FIG. 15) may be formed to be curved, thereby improving the reliability of the display device.

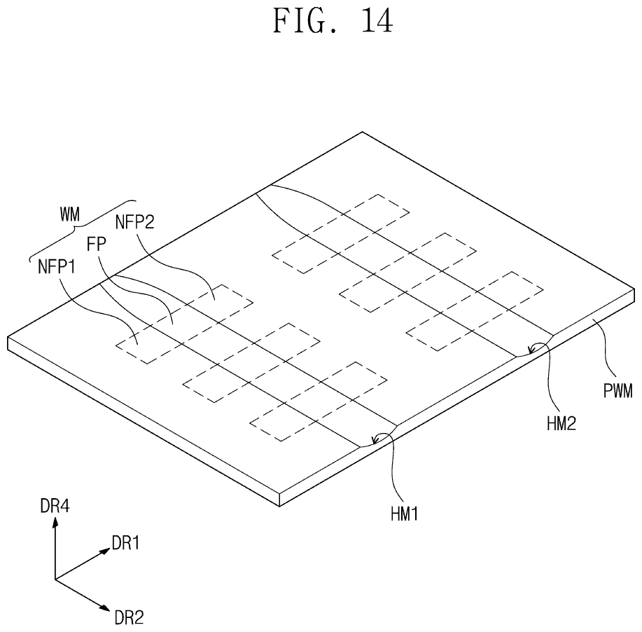

In an embodiment and referring to FIGS. 13 and 14 together, in the forming of a preliminary window mother substrate PWM, a portion of the target substrate PPWM may be etched to form the preliminary window mother substrate PWM. The preliminary window mother substrate PWM is described on the assumption that the preliminary window mother substrate PWM is disposed on a plane defined by the first direction DR1 and the second direction DR2. In FIG. 14, a cutting line for forming a window WM is indicated by a dashed rectangle. The preliminary window mother substrate PWM may include a plurality of windows WM. A first groove HM1 and a second groove HM2 may be formed in a top surface of the preliminary window mother substrate PWM. A portion of the target substrate PPWM may be etched by the first mixed fluid FFL1, the first etching fluid EFL1, and the second mixed fluid FFL2 to form the first groove HM1. A portion of the target substrate PPWM may be etched by the third mixed fluid FFL3, the second etching fluid EFL2, and the fourth mixed fluid FFL4 to form the second groove HM2.

In an embodiment and referring to FIGS. 15 and 16, the first non-folding portion NFP1 included in the window WM may include a first non-folding surface NFPS1 directed parallel to the first direction DR1, and the second non-folding portion NFP2 of the window WM may include a second non-folding surface NFPS2 directed parallel to the first direction DR1. The window WM is described on the assumption that the window WM is disposed on a plane defined by the first direction DR1 and the second direction DR2.

In an embodiment, the folding portion FP included in the window WM may include a flat surface PP directed parallel to the first direction DR1, a first folding surface FPS1 which connects the flat surface PP and the first non-folding surface NFPS1 to each other, and a second folding surface FPS2 which connects the flat surface PP and the second non-folding surface NFPS2 to each other. A width L1 of the folding portion FP in the first direction DR1 may be about 1 mm to about 25 mm. For example, the width L1 of the folding portion FP in the first direction DR1 may be about 20 mm. A width L2 of the flat surface PP in the first direction DR1 may be about 0.5 mm to about 20 mm. For example, the width L2 of the flat surface PP in the first direction DR1 may be about 15 mm.

In an embodiment, each of a portion disposed adjacent to a boundary between the first non-folding portion NFP1 and the folding portion FP and a portion disposed adjacent to a boundary between the second non-folding portion NFP2 and the folding portion FP may be formed to be curved. Each of a portion, which is disposed adjacent to the first non-folding surface NFPS1, of the first folding surface FPS1, a portion, which is disposed adjacent to the flat surface PP, of the first folding surface FPS1, a portion, which is disposed adjacent to the second non-folding surface NFPS2, of the second folding surface FPS2, and a portion, which is disposed adjacent to the flat surface PP, of the second folding surface FPS2 may be formed to be curved.

In a method for manufacturing a window, according to an embodiment, a nozzle which provides an etchant, and a nozzle which is disposed adjacent thereto and provides deionized water, may provide the etchant and the deionized water, respectively, on a target substrate at the same time to form a mixed fluid in which the etchant and the deionized water are mixed. Thus, a boundary between a folding portion and a non-folding portion may be formed to be curved. Accordingly, the window in which a phenomenon in which the boundary between the folding portion and the non-folding portion is visible is improved may be manufactured through a simple process, thereby improving process complexity.

In an embodiment, the etching device may use the first nozzle which injects the deionized water, and the second nozzle which is disposed adjacent to the first nozzle and injects the etchant, thereby manufacturing the window with the foldable characteristic and with the improved reliability through the simple process.

In addition, in an embodiment, the method for manufacturing the window may use the etching device to manufacture the window with the foldable characteristic and with the improved reliability through the simple process, thereby improving the process complexity.

Although embodiments of the invention have been described, it is understood that the invention should not be limited to these embodiments but various changes and modifications can be made by one ordinary skilled in the art within the spirit and scope of the invention. Therefore, the technical scope of the invention is not limited to the contents described in the detailed description of the specification.

What is claimed is:

1. An etching device comprising:
a stage on which a target substrate is disposed; and
a nozzle part opposing the stage with the target substrate disposed therebetween,
wherein the stage comprises a first surface directed parallel to a plane defined by a first direction and a second direction crossing the first direction, and a second surface directed parallel to a third direction which forms a first angle with the second direction,
wherein the second surface comprises a first side directed parallel to the first direction, and a second side opposing the first side in the third direction and disposed adjacent to the first surface,
wherein the nozzle part comprises a (1-1)-th nozzle, a (1-2)-th nozzle spaced apart from the (1-1)-th nozzle in the first direction, and a (2-1)-th nozzle disposed between the (1-1)-th nozzle and the (1-2)-th nozzle,
wherein each of the (1-1)-th nozzle and the (1-2)-th nozzle provides deionized water (DI) toward the first side, and
the (2-1)-th nozzle provides a first etchant toward the first side.

2. The etching device of claim 1, wherein the first angle is about 1° to about 10°.

3. The etching device of claim 1, wherein the first etchant comprises a fluorine-containing compound.

4. The etching device of claim 1, wherein a distance by which the (1-1)-th nozzle and the (1-2)-th nozzle are spaced apart from each other in the first direction is about 1 mm to about 30 mm.

5. The etching device of claim 1, wherein a distance by which the (1-1)-th nozzle and the (2-1)-th nozzle are spaced apart from each other in the first direction, and a distance by which the (2-1)-th nozzle and the (1-2)-th nozzle are spaced apart from each other in the first direction, are each independently about 0.5 mm to about 15 mm.

6. The etching device of claim 1, wherein a distance by which the (1-1)-th nozzle and the (2-1)-th nozzle are spaced apart from each other in the first direction, and a distance by which the (2-1)-th nozzle and the (1-2)-th nozzle are spaced apart from each other in the first direction, are substantially the same.

7. The etching device of claim 1, wherein the nozzle part further comprises a (1-3)-th nozzle spaced apart from the (1-2)-th nozzle in the first direction, a (1-4)-th nozzle spaced apart from the (1-3)-th nozzle in the first direction, and a (2-2)-th nozzle disposed between the (1-3)-th nozzle and the (1-4)-th nozzle,
wherein each of the (1-3)-th nozzle and the (1-4)-th nozzle provides deionized water toward the first side, and
the (2-2)-th nozzle provides a second etchant toward the first side.

8. The etching device of claim 1, wherein the nozzle part further comprises a (1-5)-th nozzle, a (1-6)-th nozzle spaced apart from the (1-5)-th nozzle in the first direction, and a (2-3)-th nozzle disposed between the (1-5)-th nozzle and the (1-6)-th nozzle,
wherein each of the (1-5)-th nozzle and the (1-6)-th nozzle provides deionized water toward the first side, and the (2-3)-th nozzle provides a third etchant toward the first side,
wherein the (1-5)-th nozzle is spaced apart from the (1-1)-th nozzle in the third direction, the (1-6)-th nozzle is spaced apart from the (1-2)-th nozzle in the third direction, and the (2-3)-th nozzle is spaced apart from the (2-1)-th nozzle in the third direction.

9. A method for manufacturing a window, the method comprising:
providing a stage comprising a first surface directed parallel to a plane defined by a first direction and a second direction crossing the first direction, and a second surface directed parallel to a third direction which forms a first angle with the second direction;
disposing, on the second surface, a target substrate comprising a third surface directed parallel to the third direction;
disposing a nozzle part so as to oppose the stage with the target substrate disposed therebetween, the nozzle part comprising a (1-1)-th nozzle, a (1-2)-th nozzle spaced apart from the (1-1)-th nozzle in the first direction, and a (2-1)-th nozzle disposed between the (1-1)-th nozzle and the (1-2)-th nozzle; and
forming a preliminary window mother substrate, the forming of the preliminary window mother substrate comprising providing deionized water on the third surface by each of the (1-1)-th nozzle and the (1-2)-th nozzle, and providing a first etchant on the third surface by the (2-1)-th nozzle,
wherein the third surface comprises a third side directed parallel to the first direction, and a fourth side opposing the third side in the third direction and disposed adjacent to the first surface,
wherein each of the (1-1)-th nozzle, the (1-2)-th nozzle, and the (2-1)-th nozzle is disposed adjacent to the third side.

10. The method of claim 9, wherein the first etchant comprises a fluorine-containing compound.

11. The method of claim 10, wherein the target substrate comprises a preliminary first non-folding portion, a preliminary second non-folding portion spaced apart from the preliminary first non-folding portion in the first direction, and a preliminary first folding portion disposed between the preliminary first non-folding portion and the preliminary second non-folding portion,
wherein, in the forming of the preliminary window mother substrate, the deionized water is provided on each of the preliminary first non-folding portion and the preliminary second non-folding portion, and the first etchant is provided on the preliminary first folding portion.

12. The method of claim 11, wherein, in the forming of the preliminary window mother substrate, the deionized water provided on the preliminary first non-folding portion through the (1-1)-th nozzle forms a first deionized fluid flowing in the third direction, the deionized water provided on the preliminary second non-folding portion through the (1-2)-th nozzle forms a second deionized fluid flowing in the third direction, and the first etchant provided on the preliminary first folding portion through the (2-1)-th nozzle forms a first etching fluid flowing in the third direction.
wherein a part of the first deionized fluid and a part of the first etching fluid are mixed to form a first mixed fluid flowing in the third direction, and a part of the second deionized fluid and a part of the first etching fluid are mixed to form a second mixed fluid flowing in the third direction,
wherein a concentration of the fluorine-containing compound in the first etching fluid is higher than each of a concentration of the fluorine-containing compound in the first mixed fluid and a concentration of the fluorine-containing compound in the second mixed fluid.

13. The method of claim 9, wherein, in the forming of the preliminary window mother substrate, each of the deionized water and the first etchant flows in the third direction.

14. The method of claim 9, further comprising, after the forming of the preliminary window mother substrate, forming a plurality of windows from the preliminary window mother substrate,
wherein each of the plurality of windows comprises a first non-folding portion, a second non-folding portion spaced apart from the first non-folding portion on the plane, and a folding portion disposed between the first non-folding portion and the second non-folding portion on the plane,
wherein a thickness of the folding portion is less than each of a thickness of the first non-folding portion and a thickness of the second non-folding portion.

15. The method of claim 14, wherein each of a portion disposed adjacent to a boundary between the first non-folding portion and the folding portion and a portion disposed adjacent to a boundary between the second non-folding portion and the folding portion is curved.

16. The method of claim 14, wherein a width of the folding portion in the first direction is about 1 mm to about 25 mm.

17. The method of claim 9, wherein the nozzle part further comprises a (1-3)-th nozzle spaced apart from the (1-2)-th nozzle in the first direction, a (1-4)-th nozzle spaced apart from the (1-3)-th nozzle in the first direction, and a (2-2)-th nozzle disposed between the (1-3)-th nozzle and the (1-4)-th nozzle,
wherein the forming of the preliminary window mother substrate further comprises providing deionized water toward the third surface by each of the (1-3)-th nozzle and the (1-4)-th nozzle, and providing a second etchant toward the third surface by the (2-2)-th nozzle,
wherein each of the (1-3)-th nozzle, the (1-4)-th nozzle, and the (2-2)-th nozzle is disposed adjacent to the third side.

18. The method of claim 9, wherein the nozzle part further comprises a (1-5)-th nozzle, a (1-6)-th nozzle spaced apart from the (1-5)-th nozzle in the first direction, and a (2-3)-th nozzle disposed between the (1-5)-th nozzle and the (1-6)-th nozzle,
wherein the forming of the preliminary window mother substrate further comprises providing deionized water toward the third surface by each of the (1-5)-th nozzle and the (1-6)-th nozzle, and providing a third etchant toward the third surface by the (2-3)-th nozzle,
wherein the (1-5)-th nozzle is spaced apart from the (1-1)-th nozzle in the third direction, the (1-6)-th nozzle is spaced apart from the (1-2)-th nozzle in the third direction, and the (2-3)-th nozzle is spaced apart from the (2-1)-th nozzle in the third direction.

19. The method of claim 9, wherein the target substrate comprises a preliminary first non-folding portion, a preliminary second non-folding portion spaced apart from the preliminary first non-folding portion in the first direction, and a preliminary first folding portion disposed between the preliminary first non-folding portion and the preliminary second non-folding portion,
wherein in the forming of the preliminary window mother substrate, the deionized water is provided on each of the preliminary first non-folding portion and the preliminary second non-folding portion, and the first etchant is provided on the preliminary first folding portion.

20. An electronic device comprising:
a display module;
an upper module comprising a window disposed above the display module; and
a lower module disposed below the display module,
wherein the window comprises a first non-folding portion, a second non-folding portion spaced apart from the first non-folding portion on a plane, and a folding portion disposed between the first non-folding portion and the second non-folding portion on the plane,
wherein each of a portion disposed adjacent to a boundary between the first non-folding portion and the folding portion and a portion disposed adjacent a boundary between the second non-folding portion and the folding portion is curved.
